(19) United States
(12) Patent Application Publication
(10) Pub. No.: US 2025/0285570 A1
(43) Pub. Date: Sep. 11, 2025

(54) DRIVER CHIP, AND STATE SELF-TEST METHOD THEREFOR

(71) Applicant: Hefei Visionox Technology Co., Ltd., Hefei (CN)

(72) Inventor: Fengzhang HU, Hefei (CN)

(73) Assignee: Hefei Visionox Technology Co., Ltd., Hefei (CN)

(21) Appl. No.: 19/218,345

(22) Filed: May 25, 2025

(30) Foreign Application Priority Data
Jun. 7, 2024 (CN) 202410744133.3

(51) Int. Cl. G09G 3/00; G01R 31/317

(52) U.S. Cl. CPC G09G 3/006; G01R 31/31724

(57) ABSTRACT

Embodiments of the present application disclose a driver chip, and a state self-test method therefor. Initialization of first-type registers is performed based on a received initialization instruction, and an auxiliary check value is received. When a state self-test instruction is received, a checked value is calculated based on actual register values of the first-type registers, and whether an operating state of the driver chip is abnormal is determined by determining whether a relationship between the checked value and the auxiliary check value meets a preset condition.

### CROSS REFERENCE TO RELATED APPLICATION

This application claims priority to Chinese Patent Application No. 202410744133.3, filed on Jun. 7, 2024, which is incorporated herein by reference in its entirety.

### TECHNICAL FIELD

The present application relates to the field of display technologies, and in particular, to a driver chip, and a state self-test method therefor.

### BACKGROUND OF THE DISCLOSURE

With the development of display technologies, users have increasingly high requirements for the image display quality.

A display apparatus includes a driver chip. In the prior art, there is a problem that data in an internal register of the driver chip is disordered and cannot be known, which affects the display quality.

### SUMMARY OF THE DISCLOSURE

The present application provides a driver chip, and a state self-test method therefor. The method allows the driver chip to detect values stored in an internal register of the driver chip itself and find a data anomaly in a timely manner, facilitating an improvement in the display quality.

According to an aspect of the present application, there is provided a state self-test method for a driver chip, where the method is applied to the driver chip including first-type registers. The state self-test method includes:
performing initialization of the first-type registers based on a received initialization instruction, and receiving and storing an auxiliary check value;
calculating a checked value based on a received state self-test instruction and actual register values of the first-type registers; and
determining whether an operating state of the driver chip is abnormal by determining whether a relationship between the checked value and the auxiliary check value meets a preset condition.

In one embodiment, the auxiliary check value is related to target register values of the first-type registers after the initialization.

In one embodiment, the auxiliary check value is related to a sum of the target register values of the first-type registers; and
the checked value is related to a sum of the actual register values of the first-type registers.

In one embodiment, the driver chip is configured to output a data voltage to a display screen body based on received display-related data, where the first-type registers are configured to store the display-related data.

In one embodiment, the auxiliary check value is equal to the sum of the target register values of the first-type registers.

The calculating a checked value based on a received state self-test instruction and actual register values of the first-type registers includes: determining a sum of the actual register values of the first-type registers as the checked value based on the received state self-test instruction.

In one embodiment, the preset condition includes the checked value being equal to the auxiliary check value. The determining whether an operating state of the driver chip is abnormal by determining whether a relationship between the checked value and the auxiliary check value meets a preset condition includes:
comparing the checked value with the auxiliary check value to obtain a comparison result;
determining that the operating state of the driver chip is abnormal when the comparison result indicates that the checked value and the auxiliary check value are not equal; or
determining that the operating state of the driver chip is normal when the comparison result indicates that the checked value and the auxiliary check value are equal.

In one embodiment, after the determining that the operating state of the driver chip is abnormal when the comparison result indicates that the checked value and the auxiliary check value are not equal, the state self-test method further includes: returning to the step of performing initialization of the first-type registers based on a received initialization instruction, and receiving and storing an auxiliary check value.

In one embodiment, the auxiliary check value is equal to a difference between a preset value and the sum of the target register values of the first-type registers.

The calculating a checked value based on a received state self-test instruction and actual register values of the first-type registers includes: determining a sum of the actual register values of the first-type registers as the checked value based on the received state self-test instruction.

In one embodiment, the preset condition is a sum of the checked value and the auxiliary check value being equal to the preset value. The determining whether an operating state of the driver chip is abnormal by determining whether a relationship between the checked value and the auxiliary check value meets a preset condition includes:
comparing the sum of the checked value and the auxiliary check value with the preset value to obtain a comparison result; and
determining that the operating state of the driver chip is abnormal when the comparison result indicates that the sum and the preset value are not equal; or
determining that the operating state of the driver chip is normal when the comparison result indicates that the sum and the preset value are equal.

In one embodiment, after the determining that the operating state of the driver chip is abnormal when the comparison result indicates that the sum and the preset value are not equal, the state self-test method further includes: returning to the step of performing initialization of the first-type registers based on a received initialization instruction, and receiving and storing an auxiliary check value.

In one embodiment, the driver chip further includes second-type registers. The performing initialization of the first-type registers based on a received initialization instruction, and receiving and storing an auxiliary check value includes:
performing the initialization of the first-type registers based on the received initialization instruction, and receiving the auxiliary check value and storing the auxiliary check value in the second-type registers.

In one embodiment, the auxiliary check value is equal to a difference between a preset value and the sum of the target register values of the first-type registers. The checked value is equal to a difference between the preset value and a sum of the actual register values of the first-type registers. The preset value is equal to a maximum register value that the second-type registers are able to store.

In one embodiment, the second-type registers include a first register, wherein the auxiliary check value is stored in the first register.

In one embodiment, the driver chip is configured to output a data voltage to a display screen body based on received display-related data, where the second-type registers are configured to store data other than the display-related data.

In one embodiment, at least one of the second-type registers includes a reset flag bit. Prior to the performing initialization of the first-type registers based on a received initialization instruction, and receiving and storing an auxiliary check value, the state self-test method further includes:
receiving a reset instruction, and writing a reset flag bit value included in the reset instruction into the reset flag bit; and
resetting the second-type registers when the reset flag bit value of the reset flag bit is valid.
at least one of the second-type registers includes a self-test enable flag bit. The state self-test instruction includes a self-test enable flag bit value.

The calculating a checked value based on a received state self-test instruction and actual register values of the first-type registers includes:
storing the self-test enable flag bit value in the self-test enable flag bit based on the received state self-test instruction; and
calculating the checked value based on the actual register values of the first-type registers when the self-test enable flag bit value is valid.

In one embodiment, the second-type registers further include a second register, where the second register includes the reset flag bit and the self-test enable flag bit.

In one embodiment, at least one of the second-type registers further includes a self-test result flag bit.

The determining whether an operating state of the driver chip is abnormal by determining whether a relationship between the checked value and the auxiliary check value meets a preset condition includes:
determining the operating state of the driver chip by determining whether the relationship between the checked value and the auxiliary check value meets the preset condition, and storing a first numerical value in the self-test result flag bit when the operating state of the driver chip is abnormal; and
determining the operating state of the driver chip by determining whether the relationship between the checked value and the auxiliary check value meets the preset condition, and storing a second numerical value in the self-test result flag bit when the operating state of the driver chip is normal, where the second numerical value is different from the first numerical value.

In one embodiment, the second-type registers include a second register, where the second register includes the self-test result flag bit.

In one embodiment, the second register further includes a reset flag bit, a self-test enable flag bit, a pre-check result flag bit, and at least one first check data bit. The first check data bit is used to store a first check data value. The first check data value of the first check data bit is related to a sum of numerical values of set flag bits, the set flag bits including the reset flag bit, the self-test enable flag bit, the pre-check result flag bit, and the self-test result flag bit. A numerical value stored in the pre-check result flag bit is used to represent a pre-check result of pre-checking the first check data value and the numerical values of the set flag bits.

In one embodiment, the calculating a checked value based on a received state self-test instruction and actual register values of the first-type registers includes:
writing corresponding data values into the reset flag bit, the self-test enable flag bit, the pre-check result flag bit, and the first check data bit based on the state self-test instruction;
determining a pre-check result based on a first sum value obtained by summing the data values corresponding to the reset flag bit, the self-test enable flag bit, the pre-check result flag bit, and the first check data bit, where when the first sum value is not equal to a first set value, it is determined that the pre-check result is incorrect; and when the first sum value is equal to the first set value, it is determined that the pre-check result is correct;
writing a third numerical value into the pre-check result flag bit when the pre-check result is incorrect; or
writing a fourth numerical value into the pre-check result flag bit when the pre-check result is correct, and calculating the checked value based on the actual register values of the first-type registers when a self-test enable flag bit value of the self-test enable flag bit is valid, where the third numerical value is different from the fourth numerical value.

In one embodiment, the data value corresponding to the pre-check result flag bit and included in the state self-test instruction is the fourth numerical value.

In one embodiment, the state self-test instruction includes an invalid reset flag bit value corresponding to the reset flag bit.

In one embodiment, the state self-test instruction further includes self-test interval time data.

The calculating a checked value based on a received state self-test instruction and actual register values of the first-type registers includes:
obtaining a self-test interval time based on the self-test interval time data in the state self-test instruction, and calculating the checked value once based on the actual register values of the first-type registers every self-test interval time.

In one embodiment, the driver chip further includes second-type registers, where the self-test interval time is stored in the second-type registers.

In one embodiment, the second-type registers include a third register, where the third register includes a self-test interval time data bit, and the self-test interval time data is stored in the self-test interval time data bit.

In one embodiment, the third register further includes at least one second check data bit, where a second check data value of the second check data bit is related to a self-test interval time data value of the self-test interval time data bit.

In one embodiment, the determining whether an operating state of the driver chip is abnormal by determining whether a relationship between the checked value and the auxiliary check value meets a preset condition includes:
obtaining a self-test result by determining whether the relationship between the checked value and the auxiliary check value meets the preset condition; and determining, based on the self-test result and a signal output by at least one functional circuit module in the driver chip, whether the operating state of the driver chip is abnormal.

In one embodiment, a self-test result is obtained by determining whether the relationship between the checked value and the auxiliary check value meets the preset condition; it is determined that the operating state of the driver chip is normal, when the self-test result is normal and the signal output by the at least one functional circuit module in the driver chip is a first level signal; or it is determined that the operating state of the driver chip is abnormal, when the self-test result is abnormal or the signal output by the at least one functional circuit module in the driver chip is a second level signal.

In one embodiment, the state self-test method further includes:
reporting, when the operating state is abnormal, an abnormal operating state through a communication pin connected to the functional circuit module.

In one embodiment, the functional circuit module includes a clock lock detection circuit configured to output an out-of-lock signal when data received by the driver chip is out of lock.

In one embodiment, the driver chip further includes second-type registers, at least one of the second-type registers including a self-test enable flag bit. The state self-test method further includes: determining that the self-test result is normal when the self-test enable flag bit has an invalid value.

In one embodiment, after the determining whether an operating state of the driver chip is abnormal by determining whether a relationship between the checked value and the auxiliary check value meets a preset condition, the state self-test method further includes:
reporting, upon determining that the operating state of the driver chip is abnormal, an abnormal operating state based on a received self-test state query request or reporting the abnormal operating state actively.

According to another aspect of the present application, there is provided another state self-test method for a driver chip, where the method is applied to a timing controller. The state self-test method includes:
sending an initialization instruction to the driver chip, the initialization instruction comprising target register values of first-type registers in the driver chip, determining an auxiliary check value based on the target register values, and sending the auxiliary check value to the driver chip;
sending a state self-test instruction to the driver chip; and
receiving an operating state reported by the driver chip.

In one embodiment, prior to the receiving an operating state reported by the driver chip, the state self-test method further includes:
sending a self-test state query request to the driver chip.

In one embodiment, the sending a state self-test instruction to the driver chip includes: sending the state self-test instruction to the driver chip, so that the driver chip calculates a checked value based on actual register values of the first-type registers after receiving the state self-test instruction, and determines whether the operating state of the driver chip is abnormal by determining whether a relationship between the checked value and the auxiliary check value meets a preset condition.

In one embodiment, the driver chip further includes second-type registers, the second-type registers including a second register. Prior to the sending a self-test state query request to the driver chip, the state self-test method further includes: reading numerical values of set flag bits and a first check data value of a first check data bit in the second register in the driver chip, and calculating a sum of the numerical values of the set flag bits and the first check data value to obtain a first sum value. The set flag bits include a reset flag bit, a self-test enable flag bit, a pre-check result flag bit, and a self-test result flag bit.

The state self-test method further includes: sending the self-test state query request to the driver chip when the first sum value is equal to a first set value; or returning to the step of reading numerical values of set flag bits and a first check data value of a first check data bit in the second register in the driver chip, and calculating a sum of the numerical values of the set flag bits and the first check data value to obtain a first sum value, when the first sum value is not equal to the first set value.

In one embodiment, the driver chip further includes second-type registers, the second-type registers including a third register. Prior to the sending a self-test state query request to the driver chip, the state self-test method further includes: reading a self-test interval time data value of a self-test interval time data bit and a second check data value of a second check data bit in the third register in the driver chip, and calculating a sum of the self-test interval time data value and the second check data value to obtain a second sum value.

The state self-test method further includes: sending the self-test state query request to the driver chip when the second sum value is equal to a second set value; or returning to the step of reading a self-test interval time data value of a self-test interval time data bit and a second check data value of a second check data bit in the third register in the driver chip, and calculating a sum of the self-test interval time data value and the second check data value to obtain a second sum value, when the second sum value is not equal to the second set value.

According to still another aspect of the present application, there is provided a driver chip, which includes first-type registers, a storage module, a calculation module, and a determination module,
where the calculation module is electrically connected to the first-type registers and the determination module, and is configured to calculate a checked value based on actual register values of the first-type registers; the storage module is configured to store an auxiliary check value; and the determination module is electrically connected to the storage module, and is configured to determine whether an operating state of the driver chip is abnormal by determining whether a relationship between the auxiliary check value and the checked value meets a preset condition.

In one embodiment, the auxiliary check value is related to target register values of the first-type registers after initialization.

In one embodiment, the calculation module includes a first adder configured to add the actual register values of the first-type registers to obtain a sum of the actual register values of the first-type registers.

In one embodiment, the sum of the actual register values of the first-type registers is used as the checked value; the auxiliary check value is equal to a sum of the target register values of the first-type registers; and the determination module includes a comparator configured to compare the checked value with the auxiliary check value and output a comparison result to determine whether the operating state of the driver chip is abnormal.

In one embodiment, the sum of the actual register values of the first-type registers is used as the checked value; the auxiliary check value is equal to a difference between a preset value and the sum of the target register values of the first-type registers; the calculation module further includes a second adder configured to sum the checked value and the auxiliary check value to obtain a checked sum value; and the determination module includes a comparator configured to compare the checked sum value with the preset value and output a comparison result to determine whether the operating state of the driver chip is abnormal.

In one embodiment, the storage module includes second-type registers, where the auxiliary check value is stored in the second-type registers.

In one embodiment, the driver chip further includes a functional circuit module. The determination module further includes an AND gate, where an output terminal of the comparator is electrically connected to a first input terminal of the AND gate, an output terminal of the functional circuit module is electrically connected to a second input terminal of the AND gate, and an output terminal of the AND gate is electrically connected to a communication pin of the driver chip.

In one embodiment, the functional circuit module includes a clock lock detection circuit configured to output an out-of-lock signal when data received by the driver chip is out of lock.

According to the embodiments of the present application, the driver chip performs the initialization of the first-type registers based on the received initialization instruction, and receives the auxiliary check value. Upon receiving the state self-test instruction, the driver chip may calculate the checked value based on the actual register values of the first-type registers, and determine whether the operating state of the driver chip is abnormal by determining whether the relationship between the checked value and the auxiliary check value meets the preset condition. The checked value is related to the actual register values of the first-type registers, and the auxiliary check value is related to the target register values of the first-type registers after the initialization. A condition that the relationship between the checked value and the auxiliary check value should meet in the normal operating state of the driver chip is used as the preset condition, and whether the operating state of the driver chip is abnormal is determined by determining whether the relationship between the checked value and the auxiliary check value meets the preset condition. This realizes self-testing of the operating state of the driver chip, and thus allows timely detection of the abnormal operating state indicating disordered data stored in the first-type registers, so that the timing controller can learn about the abnormal operating state of the driver chip in a timely manner, improving the operational reliability of the driver chip and facilitating an improvement in the display quality.

It should be understood that the content described in this section is neither intended to limit key or essential features of the embodiments of the present application, nor is it intended to limit the scope of the present application. Other features of the present application will be readily understood through the following description.

### BRIEF DESCRIPTION OF DRAWINGS

To describe the embodiments of the present application more clearly, the following briefly describes the accompanying drawings required for describing the embodiments. Apparently, the accompanying drawings in the following description show merely some embodiments of the present application.

FIG. 1 is a flowchart of a state self-test method for a driver chip according to an embodiment of the present application;

FIG. 2 is a schematic diagram of a connection relationship between driver chips and a timing controller;

FIG. 3 is a flowchart of another state self-test method for a driver chip according to an embodiment of the present application;

FIG. 4 is a flowchart of another state self-test method for a driver chip according to an embodiment of the present application;

FIG. 5 is a flowchart of another state self-test method for a driver chip according to an embodiment of the present application;

FIG. 6 is a schematic diagram of data bits of a second register;

FIG. 7 is a flowchart of another state self-test method for a driver chip according to an embodiment of the present application;

FIG. 8 is a flowchart of another state self-test method for a driver chip according to an embodiment of the present application;

FIG. 9 is a flowchart of a state self-test method for a driver chip according to an embodiment of the present application;

FIG. 10 is a flowchart of another state self-test method for a driver chip according to an embodiment of the present application;

FIG. 11 is a flowchart of another state self-test method for a driver chip according to an embodiment of the present application;

FIG. 12 is a flowchart of another state self-test method for a driver chip according to an embodiment of the present application;

FIG. 13 is a flowchart of still another state self-test method for a driver chip according to an embodiment of the present application;

FIG. 14 is a schematic diagram of a structure of a driver chip according to an embodiment of the present application;

FIG. 15 is a schematic diagram of another structure of a driver chip according to an embodiment of the present application;

FIG. 16 is a schematic diagram of another structure of a driver chip according to an embodiment of the present application; and

FIG. 17 is a schematic diagram of another structure of a driver chip according to an embodiment of the present application.

### DETAILED DESCRIPTION OF THE DISCLOSURE

The embodiments of the present application will be described below clearly and completely with reference to the accompanying drawings in the embodiments of the present application. Apparently, the embodiments described are merely some rather than all of the embodiments of the present application.

It should be noted that the terms such as “first”, “second”, “target”, and “actual” in the description and the claims of the present application and in the aforementioned accompanying drawings are used to distinguish similar objects, and do not necessarily describe a specific order of precedence. It should be understood that the data used in this way can be interchanged where appropriate, such that the embodiments of the present application described herein can be implemented in a sequence other than those illustrated or described herein. In addition, the term “include/comprise” and any variations thereof are intended to cover non-exclusive inclusions. For example, a process, a method, a SYSTEM, a product, or a device that includes a series of steps or units is not necessarily limited to those steps or units that are explicitly listed, but may include other steps or units not explicitly listed or inherent to such a process, method, product or device.

As described in the Background section, in the prior art, there is a problem that data in an internal register of the driver chip is disordered and cannot be known, which affects the display quality. The inventor has found through research that the reason for the above problem is that electromagnetic interference, such as electromagnetic interference caused by static electricity or other factors, is inevitable in an operating environment of a display apparatus, which makes the data stored in an internal register of the driver chip anomalous. A portion of the internal register in the driver chip is configured to store display-related data, an anomaly in the display-related data may result in an abnormal display image, thus affecting the display quality. In the prior art, the driver chip is unable to detect an anomaly in data in the internal register, causing poor display quality of the display apparatus.

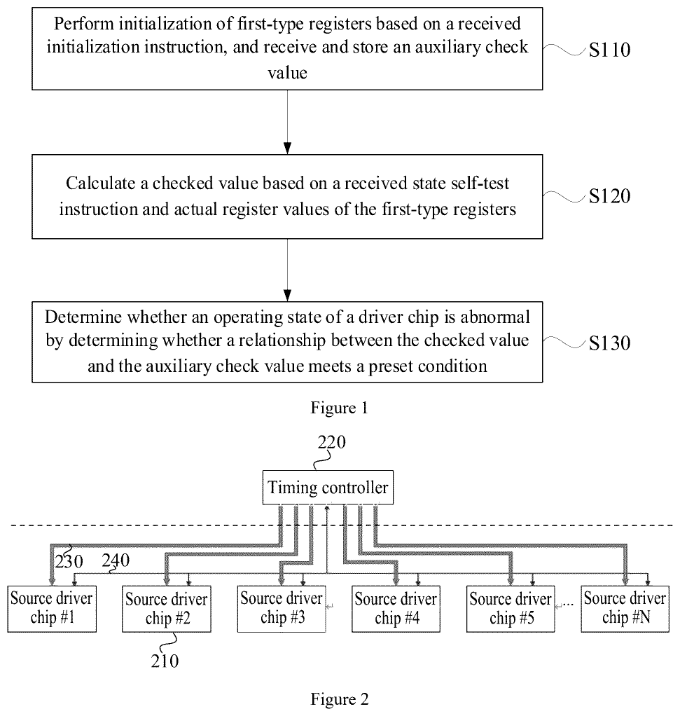

Based on the above reasons, an embodiment of the present application provides a state self-test method for a driver chip. The state self-test method may be used to detect whether data stored in an internal register of the driver chip is disordered, where the internal register includes first-type registers, and the state self-test method may be specifically used to detect whether data stored in the first-type registers is disordered. The method may be performed by the driver chip. Herein, the driver chip may be a source driver chip. The source driver chip may output a data voltage to a sub-pixel in a display screen body, and the sub-pixel in the display screen body may display a display image based on the corresponding data voltage. FIG. 1 is a flowchart of a state self-test method for a driver chip according to an embodiment of the present application. As shown in FIG. 1, the state self-test method for a driver chip includes the following steps.

S110: Perform initialization of the first-type registers based on a received initialization instruction, and receive and store an auxiliary check value.

In one embodiment, the auxiliary check value is related to target register values of the first-type registers after the initialization.

Specifically, the driver chip may be connected to a timing controller. FIG. 2 is a schematic diagram of a connection relationship between driver chips and a timing controller. Referring to FIG. 2, driver chips 210 are connected to the timing controller 220 through a data channel 230 and an instruction channel 240. The display apparatus may include one driver chip, or may include a plurality of driver chips (as shown in FIG. 2). In a small-sized display apparatus, one driver chip may be included. In a medium-sized or large-sized display apparatus, at least two driver chips may be included. The driver chip may be a source driver chip shown in FIG. 2. As shown in FIG. 2, the display apparatus may include a source driver chip #1, a source driver chip #2, a source driver chip #3, a source driver chip #4, a source driver chip #5, . . . , and a source driver chip #N. Herein, the timing controller may send display-related data to the driver chip through the data channel, and the driver chip may output a data voltage to the display screen body based on the display-related data. The driver chip includes first-type registers. The first-type registers may be configured to store the display-related data. The timing controller may send an instruction to the driver chip through the instruction channel, and the driver chip may also send an instruction to the timing controller through the instruction channel. Herein, a point to point (P2P) signal transmission protocol is applicable in the communication between the timing controller and the driver chip.

In this step, the driver chip may perform the initialization of the first-type registers based on the received initialization instruction, where the initialization instruction may be sent by the timing controller to the driver chip through the instruction channel. Herein, the initialization instruction may contain information about the target register values corresponding to individual registers included in the first-type registers, and the driver chip performs the initialization of the first-type registers based on the initialization instruction. Herein, the target register values are target numerical values stored after the initialization of the first-type registers. In the first-type registers, different registers may correspond to different target register values.

The timing controller may also send the auxiliary check value to the driver chip, where the auxiliary check value may be calculated by the timing controller based on the target register values of the first-type registers. After receiving the auxiliary check value, the driver chip stores the auxiliary check value for use in subsequent steps.

S120: Calculate a checked value based on a received state self-test instruction and actual register values of the first-type registers.

Herein, the state self-test instruction may be sent by the timing controller to the driver chip through the instruction channel. Specifically, the actual register values of the first-type registers are numerical values actually stored in the first-type registers. In the first-type registers, different registers may actually store different numerical values.

In the above step of performing initialization of the first-type registers, when the initialization is normal, the actual register values of the registers included in the first-type registers are equal to the corresponding target register values of the registers; or when the initialization is abnormal, the actual register value of at least one of the registers included in the first-type registers is not equal to the corresponding target register value. Since the driver chip may be located in an environment with electromagnetic interference, an initialization abnormality may occur, or after normal initialization, a register value may be changed due to the electromagnetic interference, resulting in disordered register values stored in the register. When the register value of the register is changed due to the electromagnetic interference after normal initialization, the case where the actual register value of at least one register in the first-type registers is not equal to the target register value may occur.

In this step, after receiving the state self-test instruction, the driver chip calculates the checked value based on the actual register values of the first-type registers. The calculation manner in which the driver chip calculates the checked value based on the actual register values of the first-type registers may be set in advance. For example, a preset calculation rule for calculating the checked value may be set in advance in the driver chip, and after receiving the state self-test instruction, the driver chip calculates the checked value according to the preset calculation rule.

S130: Determine whether an operating state of the driver chip is abnormal by determining whether a relationship between the checked value and the auxiliary check value meets a preset condition.

In one embodiment, the preset condition may be a condition that a magnitude relationship between the checked value and the auxiliary check value meets. In another embodiment, the preset condition may be a condition that a magnitude relationship between a preset value and a sum of the checked value and the auxiliary check value meets; or the preset condition may be a condition that a magnitude relationship between the preset value and a difference between the checked value and the auxiliary check value meets. The preset condition may be set in advance, and after the checked value and the auxiliary check value are calculated, whether the operating state of the driver chip is abnormal may be determined by determining whether the checked value and the auxiliary check value meet the preset condition. For example, when the checked value and the auxiliary check value meet the preset condition, it is determined that the operating state of the driver chip is normal; or when the checked value and the auxiliary check value do not meet the preset condition, it is determined that the operating state of the driver chip is abnormal. In one embodiment, after it is determined that the operating state of the driver chip is abnormal, an abnormal operating state is reported based on a received self-test state query request or the abnormal operating state is reported actively. Herein, the self-test state query request may be sent by the timing controller to the driver chip. This allows the timing controller to learn about the abnormal operating state of the driver chip in a timely manner, and then take corresponding measures, such as re-initialization of the driver chip, so as to restore the normal operating state of the driver chip, thus ensuring the display quality.

In one embodiment, the driver chip calculates the checked value based on the actual register values of the first-type registers in the same manner as the timing controller calculates the auxiliary check value based on the target register values of the first-type registers. For example, the driver chip determines the sum of the actual register values of the first-type registers as the checked value, and the timing controller determines the sum of the target register values of the first-type registers as the auxiliary check value. In this case, the preset condition may be the checked value being equal to the auxiliary check value.

In another embodiment, the driver chip calculates the checked value based on the actual register values of the first-type registers in a different manner than the timing controller calculates the auxiliary check value based on the target register values of the first-type registers. In this case, it is necessary to combine the calculation manner in which the driver chip calculates the checked value and the calculation manner in which the timing controller calculates the auxiliary check value, use, as the preset condition, a condition that the checked value and the auxiliary check value should meet in a normal operating state of the driver chip, and determine whether the checked value and the auxiliary check value meet the preset condition, so as to determine whether the operating state of the driver chip is abnormal.

In the state self-test method for a driver chip according to this embodiment, the driver chip may perform the initialization of the first-type registers based on the received initialization instruction, and receive the auxiliary check value. Upon receiving the state self-test instruction, the driver chip may calculate the checked value based on the actual register values of the first-type registers, and determine whether the operating state of the driver chip is abnormal by determining whether the relationship between the checked value and the auxiliary check value meets the preset condition. The checked value is related to the actual register values of the first-type registers, and the auxiliary check value is related to the target register values of the first-type registers after the initialization. A condition that the relationship between the checked value and the auxiliary check value should meet in the normal operating state of the driver chip is used as the preset condition, and whether the operating state of the driver chip is abnormal is determined by determining whether the relationship between the checked value and the auxiliary check value meets the preset condition. This realizes self-testing of the operating state of the driver chip, and thus allows timely detection of the abnormal operating state indicating disordered data stored in the first-type registers, so that the timing controller can learn about the abnormal operating state of the driver chip in a timely manner, improving the operational reliability of the driver chip and facilitating an improvement in the display quality.

On the basis of the above embodiments, the auxiliary check value is related to the sum of the target register values of the first-type registers; and the checked value is related to a sum of the actual register values of the first-type registers.

The addition calculation manner is simple, and is readily achievable in both software and hardware. Therefore, the auxiliary check value is set to be related to the sum of the target register values of the first-type registers, and the checked value is set to be related to the sum of the actual register values of the first-type registers. This can make the calculation manner in which the driver chip calculates the checked value relatively simple, improving the speed at which the driver chip calculates the checked value. The auxiliary check value may be calculated by the timing controller. In this case, setting the auxiliary check value to be related to the sum of the target register values of the first-type registers can also improve the speed at which the timing controller calculates the auxiliary check value.

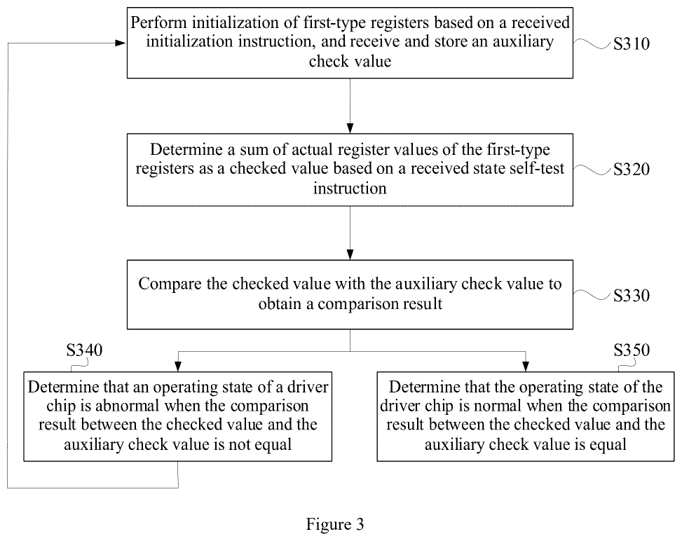

On the basis of the above embodiments, the auxiliary check value is equal to the sum of the target register values of the first-type registers. FIG. 3 is a flowchart of another state self-test method for a driver chip according to an embodiment of the present application. Referring to FIG. 3, the state self-test method for a driver chip includes the following steps.

S310: Perform initialization of first-type registers based on a received initialization instruction, and receive and store an auxiliary check value. This step has the same process as S110 in the above embodiment, and the process will not be repeated here.

S320: Determine a sum of actual register values of the first-type registers as a checked value based on a received state self-test instruction.

Specifically, in this step, after receiving the state self-test instruction, the driver chip may add the actual register values of individual registers included in the first-type registers to obtain a sum, and determine the sum of the actual register values of the registers included in the first-type registers as the checked value.

When the auxiliary check value is equal to a sum of target register values of the first-type registers and the checked value is equal to the sum of the actual register values of the first-type registers, the preset condition includes the checked value being equal to the auxiliary check value.

S330: Compare the checked value with the auxiliary check value to obtain a comparison result.

Specifically, under the condition that the first-type registers are operating normally, for any register in the first-type registers, the actual register value of the register should be equal to the target register value of the register. Accordingly, the checked value should be equal to the auxiliary check value. Therefore, in this step, the comparison result may be determined by comparing the checked value with the auxiliary check value and by determining whether the checked value is equal to the auxiliary check value.

S340: Determine that an operating state of the driver chip is abnormal when the comparison result between the checked value and the auxiliary check value is not equal.

Specifically, when the comparison result between the checked value and the auxiliary check value is not equal, it indicates that the actual register value corresponding to at least one register in the first-type registers is not equal to the target register value of the register. This means that a data error occurs in the register. The data error may be an anomaly in data stored in the register caused by electromagnetic interference. Accordingly, it can be determined that the operating state of the driver chip is abnormal.

S350: Determine that the operating state of the driver chip is normal when the comparison result between the checked value and the auxiliary check value is equal.

Specifically, when the comparison result between the checked value and the auxiliary check value is equal, it indicates that the actual register values corresponding to the registers included in the first-type registers are equal to the target register values corresponding to the registers. This means that there is no anomaly in the data stored in the first-type registers. Then, it can be determined that the operating state of the driver chip is normal.

In one embodiment, after S340 (i.e., determining that the operating state of the driver chip is abnormal), the state self-test method further includes: returning to S310 of performing initialization of first-type registers based on a received initialization instruction, and receiving and storing an auxiliary check value. This makes it possible to re-initialize the first-type registers after determining that the operating state of the driver chip is abnormal, and to perform steps S310 to S350 in a cyclic manner, until the driver chip restores to the normal operating state.

In some embodiments, an execution time of the state self-test method for a driver chip may be set. For example, the state self-test method for a driver chip may be executed at the time of power-on, or in each time of turning from screen-off to screen-on. Certainly, other set execution times are also possible. This is not specifically limited in the embodiment of the present application. After the state self-test method for a driver chip is executed and it is determined that the driver chip is in a normal operating state, the driver chip may return information indicating the normal operating state to the timing controller, and the timing controller may send display-related data to the driver chip based on a received signal indicating the normal operating state, so that the driver chip outputs a data voltage to a display screen body based on the display-related data. This ensures the normal display on the display screen body, avoiding the occurrence of disordered display images, and thus improving the display quality.

In this embodiment, the calculation manner for the checked value is simple, accelerating the calculation process for the driver chip to calculate the checked value. It should be noted that the target register values of the first-type registers during different instances of initialization may be the same or different. Specifically, for any register in the first-type registers, two different instances of initialization may correspond to the same or different target registers. Accordingly, two instances of execution of the driver chip state self-test method may correspond to the same or different auxiliary check values.

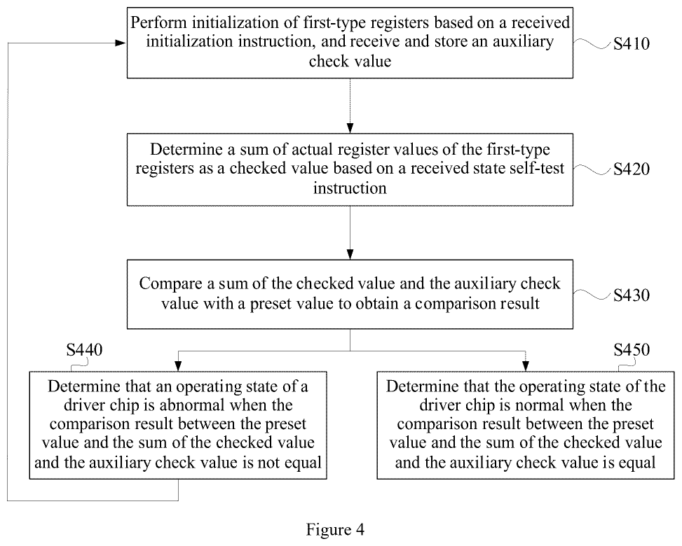

In another embodiment of the present application, the auxiliary check value is equal to a difference between the preset value and the sum of the target register values of the first-type registers. FIG. 4 is a flowchart of another state self-test method for a driver chip according to an embodiment of the present application. Referring to FIG. 4, the state self-test method for a driver chip includes the following steps.

S410: Perform initialization of first-type registers based on a received initialization instruction, and receive and store an auxiliary check value. This step has the same process as S110 in the above embodiment, and the process will not be repeated here.

S420: Determine a sum of actual register values of the first-type registers as a checked value based on a received state self-test instruction.

Herein, the preset value may be a fixed numerical value. For example, when the preset value is denoted as Y1, and the sum of the target register values of the first-type registers is denoted as Checksum1, the auxiliary check value F1=Y1−Checksum1. The sum of the actual register values of the first-type registers (that is, the checked value) is denoted as Checksum2.

In a case where the auxiliary check value is equal to a difference between the preset value and the sum of the target register values of the first-type registers, and the checked value is equal to the sum of the actual register values of the first-type registers, the preset condition is the sum of the checked value and the auxiliary check value being equal to the preset value, that is, the preset condition is Checksum2+Y1−Checksum1=Y1.

S430: Compare the sum of the checked value and the auxiliary check value with the preset value to obtain a comparison result.

Specifically, under the condition that the first-type registers is operating normally, for any register in the first-type registers, the actual register value of the register should be equal to the target register value of the register. Accordingly, Checksum2 should be equal to Checksum1, and then a checked sum value obtained by adding the checked value and the auxiliary check value should be equal to the preset value. Therefore, in this step, the comparison result may be determined by comparing the preset value with the checked sum value obtained by adding the checked value and the auxiliary check value, and by determining whether the checked sum value is equal to the preset value.

S440: Determine that the operating state of the driver chip is abnormal when the comparison result between the preset value and the sum of the checked value and the auxiliary check value is not equal.

Specifically, when the comparison result between the preset value and the sum of the checked value and the auxiliary check value is not equal, it indicates that the actual register value corresponding to at least one register in the first-type registers is not equal to the target register value of the register. This means that a data error occurs in the register. The data error may be an anomaly in data stored in the register caused by electromagnetic interference. Accordingly, it can be determined that the operating state of the driver chip is abnormal.

S450: Determine that the operating state of the driver chip is normal when the comparison result between the preset value and the sum of the checked value and the auxiliary check value is equal.

Specifically, when the comparison result between the preset value and the sum of the checked value and the auxiliary check value is equal, it indicates that the actual register values corresponding to the registers included in the first-type registers are equal to the target register values corresponding to the registers. This means that there is no anomaly in the data stored in the first-type registers. Then, it can be determined that the operating state of the driver chip is normal.

In one embodiment, after S440 (i.e., determining that the operating state of the driver chip is abnormal), the state self-test method further includes: returning to the step S410 of performing initialization of first-type registers based on a received initialization instruction, and receiving and storing an auxiliary check value. This makes it possible to re-initialize the first-type registers after determining that the operating state of the driver chip is abnormal, and to perform steps S410 to S450 in a cyclic manner, until the driver chip restores to the normal operating state. In some embodiments, an execution time of the state self-test method for a driver chip may be set. For example, the state self-test method for a driver chip may be executed at the time of power-on, or in each time of turning from screen-off to screen-on. Certainly, other set execution times are also possible. This is not specifically limited in the embodiment of the present application. After the state self-test method for a driver chip is executed and it is determined that the driver chip is in a normal operating state, the driver chip may return information indicating the normal operating state to the timing controller, and the timing controller may send display-related data to the driver chip based on a received signal indicating the normal operating state, so that the driver chip outputs a data voltage to a display screen body based on the display-related data. This ensures the normal display on the display screen body, avoiding the occurrence of disordered display images, and thus improving the display quality.

In this embodiment, the calculation manner for the checked value is combined with the preset condition, so that in S430, the checked value is always compared with a fixed preset value which may also be pre-stored in the driver chip, making the comparison rule simpler.

In some embodiments of the present application, the driver chip further includes second-type registers. S110, S310, and S410 may include: performing the initialization of the first-type registers based on the received initialization instruction, and receiving the auxiliary check value and storing the auxiliary check value in the second-type registers. Herein, the second-type registers are configured to store data other than the display-related data. The driver chip is configured to output a data voltage to a display screen body based on the received display-related data.

In one embodiment, the second-type registers may include a self-test register, which may be configured to store relevant data required for the driver chip to perform the state self-test method. The self-test register includes a first register, where the auxiliary check value is stored in the first register.

When the auxiliary check value is equal to a difference between the preset value and the sum of the target register values of the first-type registers, and the checked value is equal to a difference between the preset value and the sum of the actual register values of the first-type registers, the preset value is equal to a maximum register value that the second-type registers are able to store.

For example, when the second-type registers have a bit width of 32 bits, the preset value is equal to 0xFFFFFFFF, 0xFFFFFFFF corresponding to a decimal value of 4294967295. In one embodiment, the sum of the target register values of the first-type registers is less than or equal to the preset value.

On the basis of the above embodiments, at least one of the second-type registers includes a reset flag bit. In some embodiments, at least one of the second-type registers includes a self-test enable flag bit. The state self-test instruction includes a self-test enable flag bit value. In some embodiments, at least one of the second-type registers further includes a self-test result flag bit.

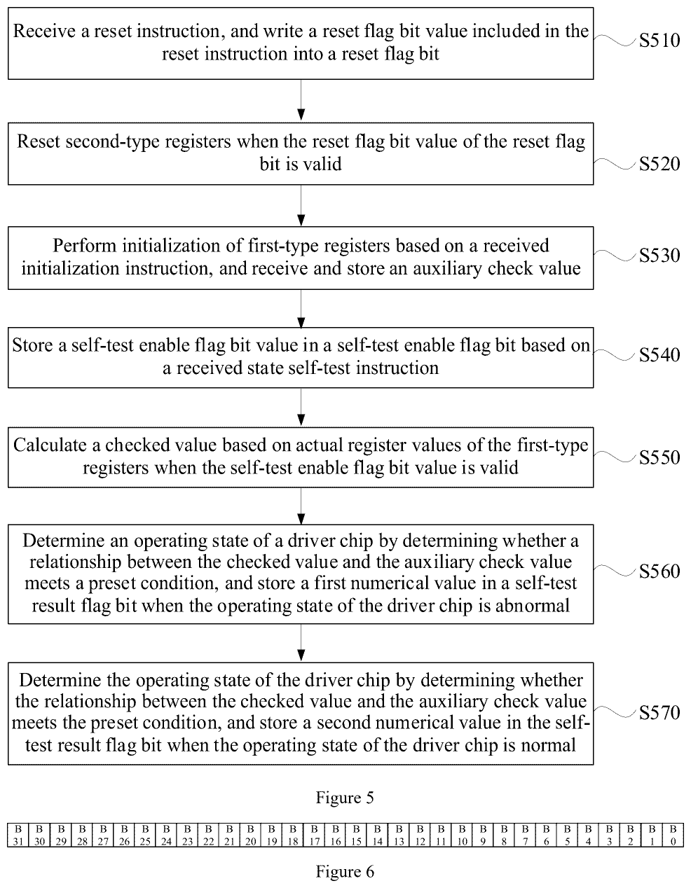

FIG. 5 is a flowchart of another state self-test method for a driver chip according to an embodiment of the present application. Referring to FIG. 5, the state self-test method for a driver chip includes the following steps.

S510: Receive a reset instruction, and write a reset flag bit value included in the reset instruction into a reset flag bit.

Herein, the reset instruction may be sent by the timing controller to the driver chip through an instruction channel. The reset instruction includes the reset flag bit value, and after receiving the reset instruction, the driver chip writes the reset flag bit value into the reset flag bit. Herein, the reset flag bit value may be a valid value or an invalid value. For example, the valid value is denoted as 1, and the invalid value is denoted as 0. When the second-type registers of the driver chip need to be reset, the timing controller may send to the driver chip a reset instruction in which the reset flag bit value is a valid value.

S520: Reset the second-type registers when the reset flag bit value of the reset flag bit is valid.

Specifically, the second-type registers include a self-test register. When the driver chip performs state self-testing, the second-type registers are first reset based on the reset instruction. This can avoid the impact of the register values stored in the second-type registers on the current state self-testing after the last execution of the state self-test method for a driver chip, thereby ensuring the accuracy of a self-test result obtained by the driver chip performing state self-testing.

S530: Perform initialization of first-type registers based on a received initialization instruction, and receive and store an auxiliary check value. This step has the same process as S110 in the above embodiment, and the process will not be repeated here.

S540: Store a self-test enable flag bit value into a self-test enable flag bit based on a received state self-test instruction.

Herein, the self-test enable flag bit value may be a valid value or an invalid value. For example, the valid value is denoted as 1, and the invalid value is denoted as 0. When the state self-testing of the driver chip needs to be enabled, the timing controller may send to the driver chip a state self-test instruction in which the self-test enable flag bit value is a valid value.

S550: Calculate a checked value based on actual register values of the first-type registers when the self-test enable flag bit value is valid.

By configuring at least one of the second-type registers to include a self-test enable flag bit, whether to calculate the checked value is determined based on the self-test enable flag bit value of the self-test enable flag bit. When the self-test enable flag bit value is valid, the checked value is calculated; or when the self-test enable flag bit value is invalid, the checked value is not calculated.

In one embodiment, the second-type registers further include a second register, where the second register includes the reset flag bit and the self-test enable flag bit. Herein, the first register in the above embodiment and the second register are different registers.

S560: Determine an operating state of the driver chip by determining whether a relationship between the checked value and the auxiliary check value meets a preset condition, and store a first numerical value in a self-test result flag bit when the operating state of the driver chip is abnormal.

S570: Determine the operating state of the driver chip by determining whether the relationship between the checked value and the auxiliary check value meets the preset condition, and store a second numerical value in the self-test result flag bit when the operating state of the driver chip is normal.

Herein, the second numerical value is different from the first numerical value.

In this way, the timing controller may determine whether the operating state of the driver chip is normal by reading the register value stored in the self-test result flag bit.

On the basis of the above embodiments, the second-type registers include a second register, the second register including the self-test result flag bit. In some embodiments, the second register further includes a reset flag bit, a self-test enable flag bit, a pre-check result flag bit, and at least one first check data bit. The first check data bit is used to store a first check data value. The first check data value of the first check data bit is related to numerical values of set flag bits, the set flag bits including the reset flag bit, the self-test enable flag bit, the pre-check result flag bit, and the self-test result flag bit. A numerical value stored in the pre-check result flag bit is used to represent a pre-check result of pre-checking the first check data value and the numerical values of the set flag bits.

In one embodiment, in the above embodiment, S120 of calculating a checked value based on a received state self-test instruction and actual register values of the first-type registers includes: writing corresponding data values into the reset flag bit, the self-test enable flag bit, the pre-check result flag bit, and the first check data bit based on the state self-test instruction; determining a pre-check result based on a first sum value obtained by summing the corresponding data values written into the reset flag bit, the self-test enable flag bit, the pre-check result flag bit, and the first check data bit, where when the first sum value is not equal to a first set value, it is determined that the pre-check result is incorrect; and when the first sum value is equal to the first set value, it is determined that the pre-check result is correct;
writing a third numerical value into the pre-check result flag bit when the pre-check result is incorrect; or writing a fourth numerical value into the pre-check result flag bit when the pre-check result is correct, and calculating the checked value based on the actual register values of the first-type registers when a self-test enable flag bit value of the self-test enable flag bit is valid, where the third numerical value is different from the fourth numerical value. After the state self-test instruction is received and the corresponding data values are written into the data bits in the second register, pre-checking is performed based on the first sum value of the corresponding data values written into the reset flag bit, the self-test enable flag bit, the pre-check result flag bit, and the first check data bit, so as to obtain the pre-check result. The pre-check result may indicate whether the current operating state of the driver chip is normal, and can also indicate whether the state self-test instruction is incorrect. Herein, when the pre-check result is correct, it means that the current operating state of the driver chip is normal and the state self-test instruction is correct; or when the pre-check result is incorrect, it means that the current operating state of the driver chip is abnormal and/or the state self-test instruction is incorrect. In this way, the driver chip may detect whether the state self-test instruction is incorrect or detect in advance that the current operating state of the driver chip is abnormal, so that the driver chip does not calculate the checked value when the state self-test instruction is incorrect. This prevents the incorrect state self-test instruction from affecting the accuracy of a state self-test result of the driver chip. Herein, the data value corresponding to the pre-check result flag bit and included in the state self-test instruction is the fourth numerical value. That is, in the state self-test instruction delivered by the timing controller to the driver chip when needing to trigger the self-testing of the driver chip, the data value corresponding to the pre-check result flag bit is a numerical value indicating that the pre-check result is correct, and the fourth numerical value in the state self-test instruction may be used as an initial value of the pre-check result flag bit. After the driver chip performs pre-checking, a corresponding numerical value may be re-written into the pre-check result flag bit based on the pre-check result. In addition, when the driver chip is normal, a first check data value of at least one first check data bit may vary with the numerical value of the pre-check result flag bit, so that the sum of the data values of the reset flag bit, the self-test enable flag bit, the pre-check result flag bit, and the first check data bit is always the first sum value.

FIG. 6 is a schematic diagram of data bits of a second register. Referring to FIG. 6, for example, the second register has a bit width of 32 bits, and the 32 data bits are B0 to B31, respectively. The second register includes a reset flag bit B0, a self-test enable flag bit B1, a pre-check result flag bit B2, and a pre-check result flag bit B3. The first check data bit may correspond to B8 to B15. With reference to FIG. 6, in one embodiment of the present application, whether the pre-check result is incorrect may be determined by determining whether a sum of a numerical value stored in one byte with bits of B0 to B7 and a numerical value stored in one byte with bits of B8 to B15 is equal to the first set value. Specifically, when the sum of the data stored in B0 to B7 and the data stored in B8 to B15 is equal to the first set value, it is determined that the pre-check result is correct; or when the sum of the data stored in B0 to B7 and the data stored in B8 to B15 is not equal to the first set value, it is determined that the state self-test instruction is incorrect. For example, the first set value may be 0xFF.

Prior to the initialization of the first-type registers, the second-type registers are reset. Therefore, the state self-test instruction may be set to include an invalid reset flag bit value corresponding to the reset flag bit, so that the driver chip does not reset the second-type registers again after receiving the state self-test instruction.

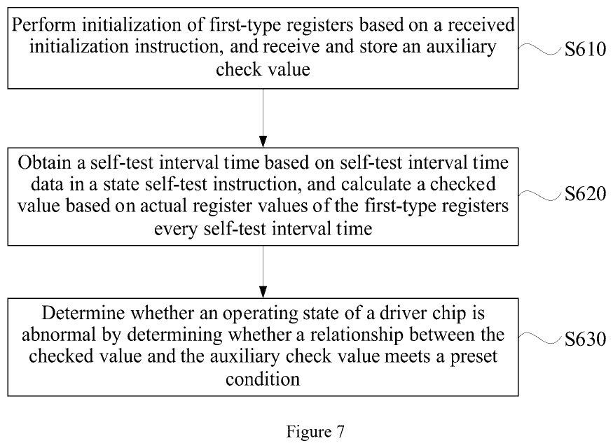

In some embodiments, the state self-test instruction further includes self-test interval time data. FIG. 7 is a flowchart of another state self-test method for a driver chip according to an embodiment of the present application. Referring to FIG. 7, the state self-test method for a driver chip includes the following steps.

S610: Perform initialization of first-type registers based on a received initialization instruction, and receive and store an auxiliary check value. This step has the same process as S110 in the above embodiment, and the process will not be repeated here.

S620: Obtain a self-test interval time based on the self-test interval time data in the state self-test instruction, and calculate the checked value based on the actual register values of the first-type registers every self-test interval time.

Specifically, the timing controller may set the self-test interval time, and send the state self-test instruction including the self-test interval time data to the driver chip through an instruction channel. The driver chip may obtain the self-test interval time based on the self-test interval time data, and calculate the checked value every self-test interval time. Each time the checked value is calculated, the following step, namely S630, is performed. In some embodiments, the state self-test instruction may further include a set number of times the checked value is calculated after one instance of initialization of the first-type registers. When the number of times the checked value is calculated every self-test interval time reaches the set number of times after one instance of initialization of the first-type registers, the calculation of the checked value is no longer performed until the next instance of initialization of the first-type registers, and then the calculation of the checked value is performed again based on the actual register values of the first-type registers every self-test interval time.

S630: Determine whether an operating state of the driver chip is abnormal by determining whether a relationship between the checked value and the auxiliary check value meets a preset condition. This step has the same process as S130 in the above embodiment, and the process will not be repeated here.

On the basis of the above embodiments, the driver chip further includes second-type registers, where the self-test interval time is stored in the second-type registers. In some embodiments, the second-type registers include a third register, where the third register includes a self-test interval time data bit, and the self-test interval time data is stored in the self-test interval time data bit. Specifically, the driver chip may write the self-test interval time data into the self-test interval time data bit in the third register based on the received state self-test instruction. When the self-test interval data bit is a valid value, the driver chip may calculate the checked value every self-test interval time. In some embodiments, when the data stored in the self-test interval time data bit is an invalid value, the driver chip may calculate the checked value every default time interval. For example, the default time interval may be 1 second. In another embodiment, when the data stored in the self-test interval time data bit is an invalid value, the driver chip may calculate the checked value based on the state self-test instruction.

On the basis of the above embodiments, the third register further includes at least one second check data bit, where a second check data value of the second check data bit is related to a self-test interval time data value of the self-test interval time data bit. Herein, the self-test interval time data value is a numerical value of the self-test interval time data.

Specifically, the second check data value may vary with the self-test interval time. when the state self-test instruction is transmitted correctly and the driver chip is in a normal operating state, a sum of the second check data value and the self-test interval time data value may be a second set value. For example, the second set value may be 0xFFFF. For example, in the third register, the self-test interval time data bits are B15 to B0, and the second check data bits are B31 to B16. At this point, when the state self-test instruction is transmitted correctly and the driver chip is in a normal operating state, a sum of a second check data value in the data bits of B15 to B0 and the self-test interval time data value in the data bits of B31 to B16 should be 0xFFFF. Subsequently, when the timing controller queries a self-test state result of the driver chip, the timing controller may first query whether the sum of the second check data value and the self-test interval time data value is equal to the second set value. If the sum of the second check data value and the self-test interval time data value is not equal to the second set value, the second check data value and the self-test interval time data value are re-read. Specifically, the sum of the second check data value and the self-test interval time data value being not equal to the second set value may be caused by interference or other accidental factors during the transmission of the state self-test instruction, that is, the state self-test instruction is transmitted incorrectly. In this case, the above problem may be overcome by obtaining the second check data value and the self-test interval time data value multiple times when the sum of the second check data value and the self-test interval time data value is not equal to the second set value. The sum of the second check data value and the self-test interval time data value being not equal to the second set value may also be caused by an abnormality in the driver chip itself. In this case, the second check data value and the self-test interval time data value are obtained multiple times when the sum of the second check data value and the self-test interval time data value is not equal to the second set value. If the sum of the second check data value and the self-test interval time data value is still not equal to the second set value, the timing controller may determine that the driver chip itself is abnormal, and no further steps for state self-testing of the driver chip are performed. When the sum of the second check data value and the self-test interval time data value is equal to the second set value, a query for a flag bit corresponding to the state self-test result in the second-type registers is made.

In this embodiment, by setting the state self-test instruction to include the self-test interval time data, so that the driver chip may calculate the checked value based on the state self-test instruction every self-test interval time and determine whether the operating state of the driver chip is abnormal, the driver chip may perform cyclic self-testing after one instance of initialization of the first-type registers, thereby avoiding inaccuracy in a self-test result of a single self-test caused by accidental factors, and improving the accuracy of the state self-test result of the driver chip.

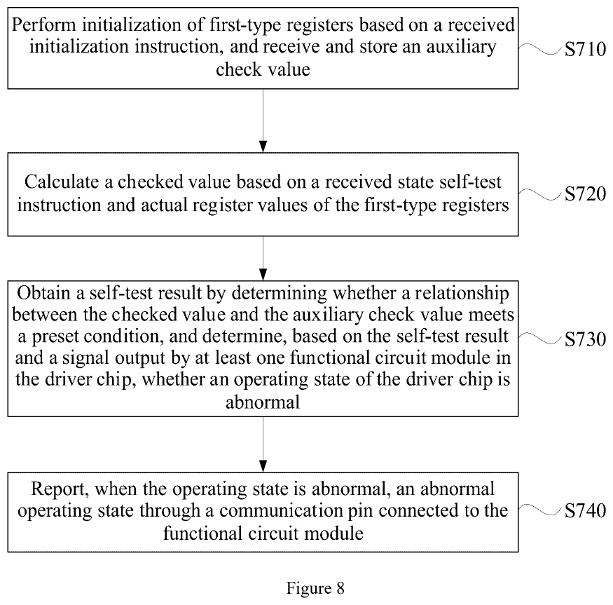

FIG. 8 is a flowchart of another state self-test method for a driver chip according to an embodiment of the present application. Referring to FIG. 8, in one embodiment, the state self-test method for a driver chip includes the following steps.

S710: Perform initialization of first-type registers based on a received initialization instruction, and receive and store an auxiliary check value. This step has the same process as S110 in the above embodiment, and the process will not be repeated here.

S720: Calculate a checked value based on a received state self-test instruction and actual register values of the first-type registers. This step has the same process as S120 in the above embodiment, and the process will not be repeated here.

S730: Obtain a self-test result by determining whether a relationship between the checked value and the auxiliary check value meets a preset condition, and determine, based on the self-test result and a signal output by at least one functional circuit module in the driver chip, whether an operating state of the driver chip is abnormal.

In one embodiment, the self-test result is obtained by determining whether the relationship between the checked value and the auxiliary check value meets the preset condition, and when the self-test result is normal and the signal output by the at least one functional circuit module in the driver chip is a first level signal, it is determined that the operating state of the driver chip is normal. The self-test result is obtained by determining whether the relationship between the checked value and the auxiliary check value meets the preset condition, and when the self-test result is abnormal and/or the signal output by the at least one functional circuit module in the driver chip is a second level signal, it is determined that the operating state of the driver chip is abnormal.

Herein, the first level signal and the second level signal are different in magnitude. For example, the first level signal is a high level signal, while the second level signal is a low level signal. Alternatively, the first level signal is a low level signal, while the second level signal is a high level signal.

S740: Report, when the operating state is abnormal, an abnormal operating state through a communication pin connected to the functional circuit module.

Specifically, the abnormal operating state is reported to the timing controller through the communication pin connected to the functional circuit module, eliminating the need for additional pins of the driver chip, thereby ensuring a small size of the driver chip. When the operating state is normal, the driver chip may report a normal operating state through the communication pin connected to the functional circuit module, or may not report the normal operating state.

In one embodiment, the functional circuit module includes a clock lock detection circuit configured to output an out-of-lock signal when data received by the driver chip is out of lock.

In one embodiment, the driver chip further includes second-type registers, at least one of the second-type registers including a self-test enable flag bit. The state self-test method further includes: determining that the self-test result is normal when the self-test enable flag bit has an invalid value. Specifically, when the self-test enable flag bit has an invalid value, the driver chip neither calculates the checked value, nor does it obtain a self-test result by determining whether the relationship between the checked value and the auxiliary check value meets the preset condition. Instead, the driver chip directly determines the self-test result as being normal, to ensure the accuracy of the operating state of the driver chip that is determined based on the signal output by the functional circuit module without performing state self-testing of the driver chip.

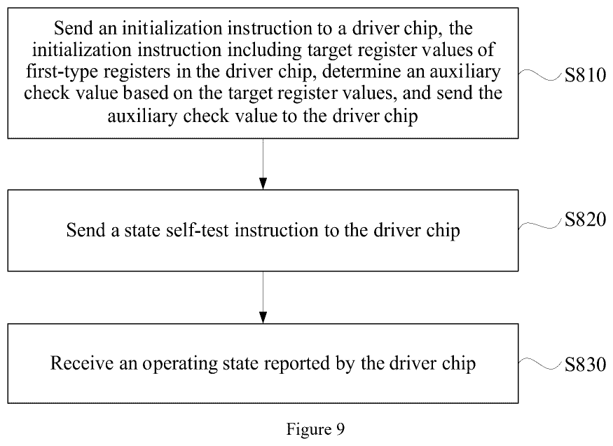

An embodiment of the present application further provides a state self-test method for a driver chip, where the method is applied to a timing controller. FIG. 9 is a flowchart of a state self-test method for a driver chip according to an embodiment of the present application. Referring to FIG. 9, in one embodiment, the state self-test method for a driver chip includes the following steps.

S810: Send an initialization instruction to the driver chip, the initialization instruction including target register values of first-type registers in the driver chip, determine an auxiliary check value based on the target register values, and send the auxiliary check value to the driver chip.

Specifically, when the driver chip performs state self-testing, the timing controller sends the initialization instruction to the driver chip, so that the driver chip may perform initialization of the first-type registers based on the initialization instruction. The initialization instruction includes the target register values of the first-type registers in the driver chip. After normal initialization of the first-type registers in the driver chip and with no disordered data in the first-type registers after the initialization, an actual register value of any register in the first-type registers is equal to the corresponding target register value of the register.

S820: Send a state self-test instruction to the driver chip.

In one embodiment, the state self-test instruction is sent to the driver chip, so that the driver chip calculates a checked value based on actual register values of the first-type registers after receiving the state self-test instruction, and determines whether an operating state of the driver chip is abnormal by determining whether a relationship between the checked value and the auxiliary check value meets a preset condition.

In one embodiment, after receiving an initialization completion state message returned by the driver chip when completing the initialization of the first-type registers, the timing controller sends the state self-test instruction to the driver chip, so that the driver chip performs the above state self-test process.

S830: Receive an operating state reported by the driver chip.

Herein, when a state self-test result of the driver chip is normal, a normal operating state may be reported to the timing controller; or when the state self-test result of the driver chip is abnormal, an abnormal operating state may be reported to the timing controller. The timing controller receives the operating state reported by the driver chip, and then may detect the abnormal operating state of the driver chip in a timely manner. This improves the operational reliability of the driver chip, and facilitates an improvement in the display quality.

In one embodiment, prior to the above step S810, the state self-test method further includes: sending a reset instruction to the driver chip, so that the driver chip resets the second-type registers when a reset flag bit value included in the reset flag bit is valid.

In the self-test method for a driver chip according to this embodiment, the timing controller sends the initialization instruction to the driver chip, determines the auxiliary check value based on the target register values of the first-type registers that are included in the initialization instruction, and sends the auxiliary check value to the driver chip. The timing controller sends the state self-test instruction to the driver chip, so that the driver chip calculates the checked value based on the actual register values of the first-type registers after receiving the state self-test instruction, and determines whether the operating state of the driver chip is abnormal by determining whether the relationship between the checked value and the auxiliary check value meets the preset condition. Then, the timing controller receives the operating state reported by the driver chip. The checked value is related to the actual register values of the first-type registers, and the auxiliary check value is related to the target register values of the first-type registers after the initialization. A condition that the relationship between the checked value and the auxiliary check value should meet in the normal operating state of the driver chip is used as the preset condition, and whether the operating state of the driver chip is abnormal is determined by determining whether the relationship between the checked value and the auxiliary check value meets the preset condition. This realizes self-testing of the operating state of the driver chip, and thus allows timely detection of the abnormal operating state indicating disordered data stored in the first-type registers, so that the timing controller can learn about the abnormal operating state of the driver chip in a timely manner, improving the operational reliability of the driver chip and facilitating an improvement in the display quality.

On the basis of the above embodiment, prior to S830, the state self-test method further includes sending a self-test state query request to the driver chip. In some embodiments, the driver chip reports a state self-test result of the driver chip based on the self-test state query request sent by the timing controller.

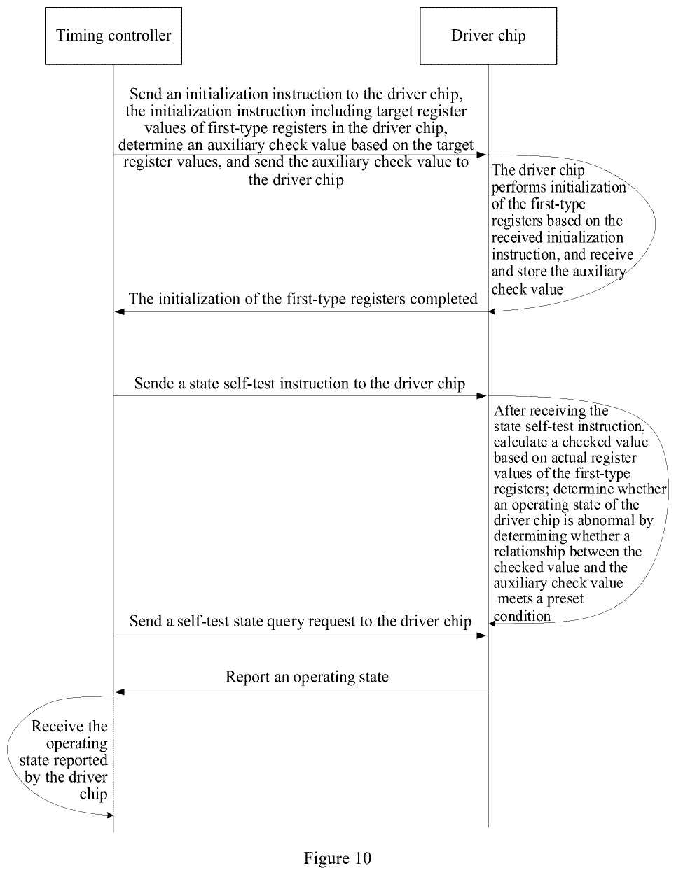

FIG. 10 is a flowchart of another state self-test method for a driver chip according to an embodiment of the present application. FIG. 10 shows an interaction process between a timing controller and a driver chip. Referring to FIG. 10, the state self-test method for a driver chip includes the following steps.

The timing controller sends an initialization instruction to the driver chip, the initialization instruction including target register values of first-type registers in the driver chip, determines an auxiliary check value based on the target register values, and sends the auxiliary check value to the driver chip;
the driver chip performs initialization of the first-type registers based on a received initialization instruction, and receives and stores an auxiliary check value; after completing the initialization of the first-type registers, the driver chip sends, to the timing controller, information indicating the completion of the initialization of the first-type registers;
the timing controller sends a state self-test instruction to the driver chip;
after receiving the state self-test instruction, the driver chip calculates a checked value based on actual register values of the first-type registers, and determines whether an operating state of the driver chip is abnormal by determining whether a relationship between the checked value and the auxiliary check value meets a preset condition;
the timing controller sends a self-test state query request to the driver chip;
the driver chip reports an operating state, where the operating state may be a normal operating state or an abnormal operating state obtained based on a state self-test result; and
the timing controller receives the operating state reported by the driver chip.

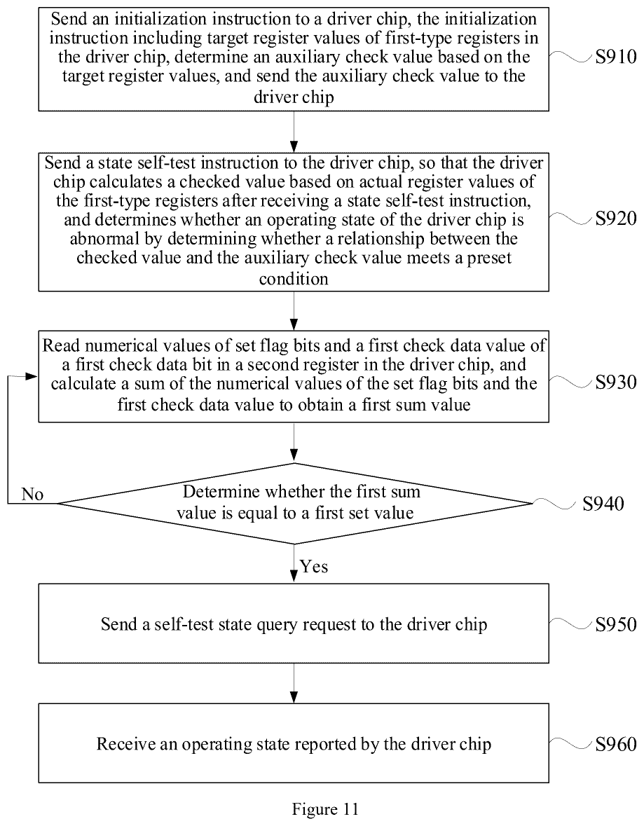

On the basis of the above embodiments, the driver chip further includes second-type registers, the second-type registers including a second register. FIG. 11 is a flowchart of another state self-test method for a driver chip according to an embodiment of the present application. The state self-test method for a driver chip can be applied to a timing controller. Referring to FIG. 11, in one embodiment, the state self-test method for a driver chip includes the following steps.

S910: Send an initialization instruction to a driver chip, the initialization instruction including target register values of first-type registers in the driver chip, determine an auxiliary check value based on the target register values, and send the auxiliary check value to the driver chip. This step has the same process as S810 in the above embodiment, and the process will not be repeated here.

S920: Send a state self-test instruction to the driver chip, so that the driver chip calculates a checked value based on actual register values of the first-type registers after receiving the state self-test instruction, and determines whether an operating state of the driver chip is abnormal by determining whether a relationship between the checked value and the auxiliary check value meets a preset condition. This step has the same process as S820 in the above embodiment, and the process will not be repeated here.

S930: Read numerical values of set flag bits and a first check data value of a first check data bit in a second register in the driver chip, and calculate a sum of the numerical values of the set flag bits and the first check data value to obtain a first sum value.

Herein, the set flag bits include a reset flag bit, a self-test enable flag bit, a pre-check result flag bit, and a self-test result flag bit.

S940: Determine whether the first sum value is equal to a first set value.

When the first sum value is equal to the first set value, S950 below is performed; or when the first sum value is not equal to the first set value, the process returns to S930. As described in the above embodiment, for example, the first set value is 0xFF.

S950: Send a self-test state query request to the driver chip.

S960: Receive an operating state reported by the driver chip. This step has the same process as S830 in the above embodiment, and the process will not be repeated here.

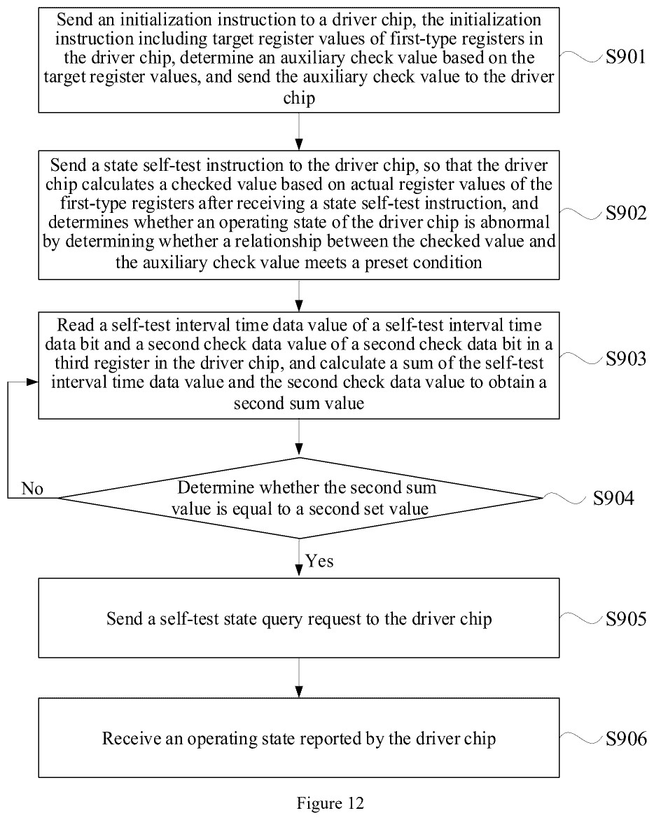

In one embodiment, the driver chip further includes second-type registers, the second-type registers including a third register. FIG. 12 is a flowchart of another state self-test method for a driver chip according to an embodiment of the present application. The state self-test method for a driver chip can be applied to a timing controller. Referring to FIG. 12, in one embodiment, the state self-test method for a driver chip includes the following steps.

S901: Send an initialization instruction to the driver chip, the initialization instruction including target register values of first-type registers in the driver chip, determine an auxiliary check value based on the target register values, and send the auxiliary check value to the driver chip. This step has the same process as S810 in the above embodiment, and the process will not be repeated here.

S902: Send a state self-test instruction to the driver chip, so that the driver chip calculates a checked value based on actual register values of the first-type registers after receiving the state self-test instruction, and determines whether an operating state of the driver chip is abnormal by determining whether a relationship between the checked value and the auxiliary check value meets a preset condition. This step has the same process as S820 in the above embodiment, and the process will not be repeated here.

S903: Read a self-test interval time data value of a self-test interval time data bit and a second check data value of a second check data bit in a third register in the driver chip, and calculate a sum of the self-test interval time data value and the second check data value to obtain a second sum value.

S904: Determine whether the second sum value is equal to a second set value.

When the second sum value is equal to the second set value, step S905 is performed; or when the second sum value is not equal to the second set value, the process returns to S903. As described in the above embodiment, for example, the second set value is 0xFFFF.

S905: Send a self-test state query request to the driver chip.

S906: Receive an operating state reported by the driver chip. This step has the same process as S830 in the above embodiment, and the process will not be repeated here.

FIG. 13 is a flowchart of still another state self-test method for a driver chip according to an embodiment of the present application. The state self-test method for a driver chip can be applied to a timing controller. Referring to FIG. 13, in one embodiment, the state self-test method for a driver chip includes the following steps.

S911: Send an initialization instruction to the driver chip, the initialization instruction including target register values of first-type registers in the driver chip, determine an auxiliary check value based on the target register values, and send the auxiliary check value to the driver chip. This step has the same process as S810 in the above embodiment, and the process will not be repeated here.

S912: Send a state self-test instruction to the driver chip, so that the driver chip calculates a checked value based on actual register values of the first-type registers after receiving the state self-test instruction, and determines whether an operating state of the driver chip is abnormal by determining whether a relationship between the checked value and the auxiliary check value meets a preset condition. This step has the same process as S820 in the above embodiment, and the process will not be repeated here.

S913: Read numerical values of set flag bits and a first check data value of a first check data bit in the second register in the driver chip, and calculate a sum of the numerical values of the set flag bits and the first check data value to obtain a first sum value; and read a self-test interval time data value of a self-test interval time data bit and a second check data value of a second check data bit in the third register in the driver chip, and calculate a sum of the self-test interval time data value and the second check data value to obtain a second sum value.

Herein, the set flag bits include a reset flag bit, a self-test enable flag bit, a pre-check result flag bit, and a self-test result flag bit.

S914: Determine whether the first sum value is equal to the first set value and whether the second sum value is equal to the second set value.

When the first sum value is equal to the first set value and the second sum value is equal to the second set value, S915 is performed; and when the first sum value is not equal to the first set value, and/or the second sum value is not equal to the second set value, the process returns to S913.

S915: Send a self-test state query request to the driver chip.

S916: Receive an operating state reported by the driver chip. This step has the same process as S830 in the above embodiment, and the process will not be repeated here.

Specifically, when the state self-test instruction sent by the timing controller is correct and no error occurs during the process of the driver chip performing state self-testing, the sum of the numerical values of the set flag bits and the numerical value of the first check data bit is equal to the first set value, or the sum of the data value of the self-test interval time data bit and the data value of the second check data bit is equal to the second set value. The above rule (i.e., the sum of the numerical values of the set flag bits and the numerical value of the first check data bit being equal to the first set value, or the sum of the data value of the self-test interval time data bit and the data value of the second check data bit being equal to the second set value) may be set in advance inside the timing controller and inside the driver chip. When the state self-test instruction sent by the timing controller is incorrect and an error occurs during the process of the driver chip performing state self-testing, the case where the sum of the numerical values of the set flag bits and the numerical value of the first check bit is not equal to the first set value, or the sum of the data value of the self-test interval time data bit and the data value of the second check data bit is not equal to the second set value may occur.

In the above embodiment, before the self-test state query request is sent to the driver chip, a relationship between the first set value and the first sum value obtained by summing the numerical values of the set flag bits and the numerical value of the first check data bit in the second register is determined first, and/or a relationship between the second set value and the second sum value obtained by summing the numerical value of the self-test interval time data bit and the numerical value of the second check data bit in the third register is determined first, and then the impact of the factor in correctness of the state self-test instruction sent by the timing controller or other factors occurring during the state self-test process on the accuracy of the state self-test result of the driver chip can be determined.

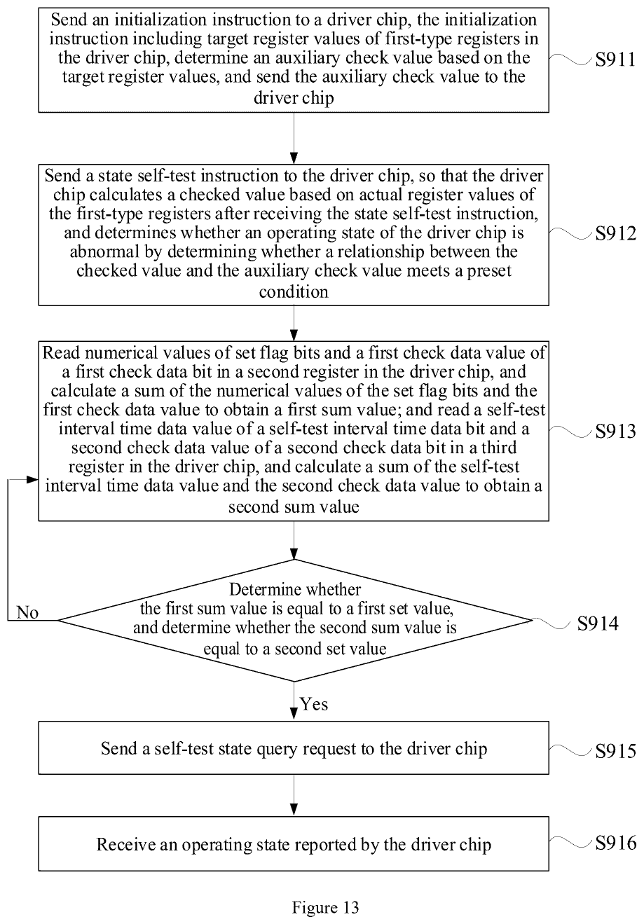

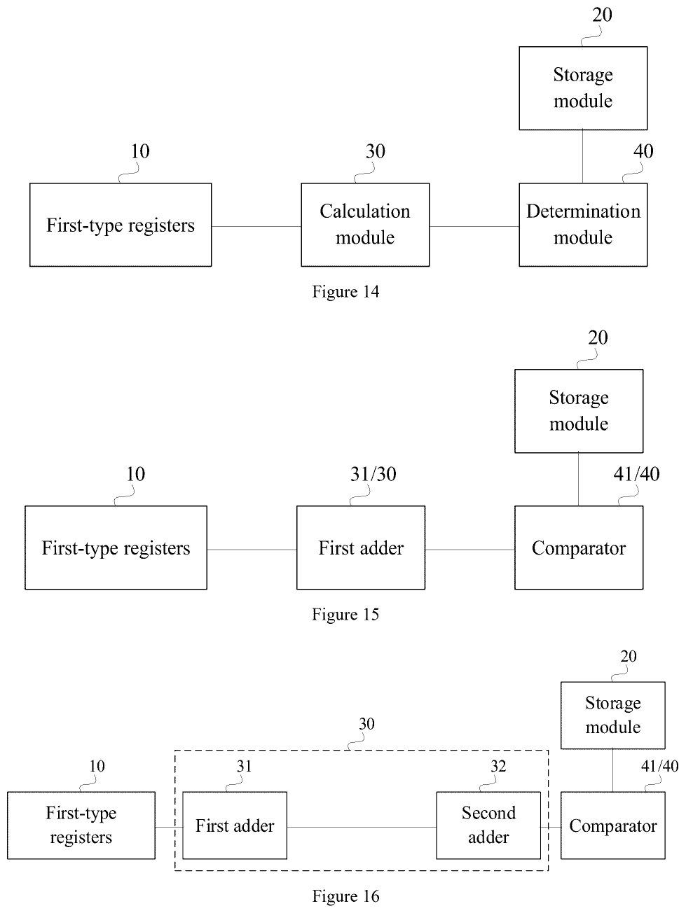

An embodiment of the present application further provides a driver chip. FIG. 14 is a schematic diagram of a structure of a driver chip according to an embodiment of the present application. Referring to FIG. 14, the driver chip includes first-type registers 10, a storage module 20, a calculation module 30, and a determination module 40. The calculation module 30 is electrically connected to the first-type registers 10 and the determination module 40, and is configured to calculate a checked value based on actual register values of the first-type registers 10. The storage module 20 is configured to store an auxiliary check value. The determination module 40 is electrically connected to the storage module 20, and is configured to determine whether an operating state of the driver chip is abnormal by determining whether a relationship between the auxiliary check value and the checked value meets a preset condition.

In one embodiment, the auxiliary check value is related to target register values of the first-type registers 10 after initialization.

In one embodiment, the storage module 20 includes second-type registers, where the auxiliary check value is stored in the second-type registers.

Specifically, after receiving an initialization instruction, the driver chip may perform initialization of the first-type registers 10 based on the initialization instruction. In some embodiments, the first-type registers are initialized directly based on the initialization instruction. The storage module 20 may store the received auxiliary check value. Based on the received state self-test instruction, the driver chip may calculate, through the calculation module 30, the checked value based on actual register values of the first-type registers 10, and determine, through the determination module 40, whether the operating state of the driver chip is abnormal by determining whether the relationship between the checked value and the auxiliary check value meets the preset condition.

The driver chip according to this embodiment is configured to execute the state self-test method for a driver chip according to any of the above embodiments of the present application, and has the beneficial effects of the state self-test method according to any of the above embodiments of the present application.

FIG. 15 is a schematic diagram of another structure of a driver chip according to an embodiment of the present application. Referring to FIG. 15, on the basis of the above embodiments, the calculation module 30 includes a first adder 31. The first adder 31 is configured to add the actual register values of the first-type registers 10 to obtain a sum of the actual register values of the first-type registers 10.

Still referring to FIG. 15, in one embodiment, the sum of the actual register values of the first-type registers 10 is used as a checked value; the auxiliary check value is equal to a sum of the target register values of the first-type registers 10; and the determination module 40 includes a comparator 41, where the comparator 41 is configured to compare the checked value with the auxiliary check value and output a comparison result to determine whether the operating state of the driver chip is abnormal.

In this embodiment, the structure of the driver chip in which the calculation module 30 includes the first adder 31 and the determination module 40 includes the comparator 41 is simple, and state self-testing of the driving chip can be implemented through a simple circuit structure.

FIG. 16 is a schematic diagram of another structure of a driver chip according to an embodiment of the present application. Referring to FIG. 16, in one embodiment, the sum of the actual register values of the first-type registers is used as the checked value; the auxiliary check value is equal to a difference between a preset value and the sum of the target register values of the first-type registers; The calculation module 30 further includes a second adder 32, where the second adder 32 is configured to sum the checked value and the auxiliary check value to obtain a checked sum value; and the determination module 40 includes a comparator 41, where the comparator 41 is configured to compare the checked sum value with the preset value and output a comparison result to determine whether the operating state of the driver chip is abnormal.

Herein, the preset value is a fixed numerical value. In the structure of the driver chip according to this embodiment, one of input signals (a preset value) into the comparator 41 is a fixed numerical value, which allows the checked value to be always compared with the fixed numerical value without the need to change one of the input signals into the comparator 41, thus making the comparison rule simpler.

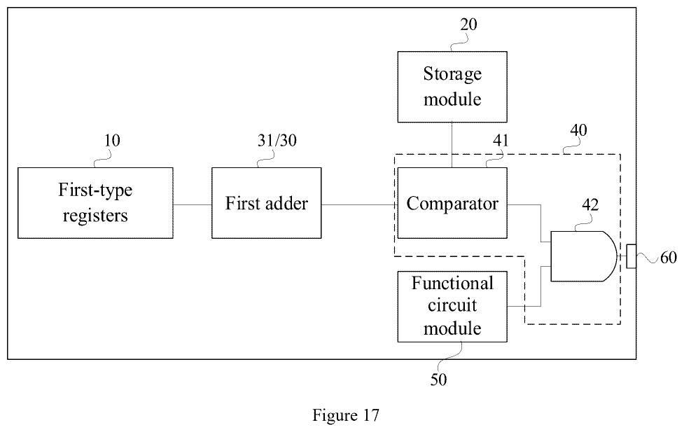

FIG. 17 is a schematic diagram of another structure of a driver chip according to an embodiment of the present application. Referring to FIG. 17, in one embodiment, the driver chip further includes a functional circuit module 50. The determination module 40 further includes an AND gate 42, where an output terminal of the comparator 41 is electrically connected to a first input terminal of the AND gate 42, an output terminal of the functional circuit module 50 is electrically connected to a second input terminal of the AND gate 42, and an output terminal of the AND gate 42 is electrically connected to a communication pin 60 of the driver chip.

In some embodiments, the functional circuit module 50 includes a clock lock detection circuit configured to output an out-of-lock signal when data received by the driver chip is out of lock. Herein, the clock lock detection circuit is an original circuit module in the driver chip. In some other embodiments, the functional circuit module may include other original circuit modules in the driver chip.

By configuring the driver chip to further include the functional circuit module 50 and configuring the determination module to further include the AND gate 42, and respectively using the output signal from the comparator 41 and the output signal from the functional circuit module 50 as two input signals into the AND gate 42, the AND gate 42 may provide outputs based on the above two input signals, and then report the abnormal operating state to the timing controller through the communication pin 60 connected to the functional circuit module 50 when the output signal from the comparator 41 is a signal corresponding to an abnormal self-test result and/or the output signal from the functional circuit module 50 is a signal corresponding to an abnormality in the functional circuit module 50 (for example, the out-of-lock signal output by the clock lock detection circuit in the functional circuit module 50). With this configuration, no additional pins of the driver chip are required, thereby ensuring a small size of the driver chip.

It should be noted that on the basis of FIG. 15, FIG. 17 provides an illustration of the determination module further including an AND gate. Alternatively, the determination module may include an AND gate on the basis of the driver chip structure shown in FIG. 16, which will not be repeated here.

It should be understood that the steps may be reordered, added, or deleted using the various forms of processes illustrated above. For example, the steps recorded in the present application may be performed in parallel, sequentially, or in a different order, provided that desired results of the embodiments of the present application can be achieved, which are not limited here.

The above detailed description does not constitute a limitation on the scope of protection of the present application. Various modifications, combinations, sub-combinations, and substitutions can be made based on design requirements and other factors. Any modifications, equivalent substitutions, or improvements made within the spirit and principle of the present application should be included within the scope of protection of the present application.

What is claimed is:

1. A state self-test method for a driver chip, applied to the driver chip comprising first-type registers, the state self-test method comprising:
performing initialization of the first-type registers based on a received initialization instruction, and receiving and storing an auxiliary check value; calculating a checked value based on a received state self-test instruction and actual register values of the first-type registers; and
determining whether an operating state of the driver chip is abnormal by determining whether a relationship between the checked value and the auxiliary check value meets a preset condition.

2. The state self-test method for a driver chip according to claim 1, wherein the auxiliary check value is related to target register values of the first-type registers after the initialization.

3. The state self-test method for a driver chip according to claim 2, wherein the auxiliary check value is related to a sum of the target register values of the first-type registers; the checked value is related to a sum of the actual register values of the first-type registers; and
the driver chip is configured to output a data voltage to a display screen body based on received display-related data, wherein the first-type registers are configured to store the display-related data.

4. The state self-test method for a driver chip according to claim 2, wherein the auxiliary check value is equal to a sum of the target register values of the first-type registers; and the calculating a checked value based on a received state self-test instruction and actual register values of the first-type registers comprises: determining a sum of the actual register values of the first-type registers as the checked value based on the received state self-test instruction.

5. The state self-test method for a driver chip according to claim 4, wherein the preset condition comprises the checked value being equal to the auxiliary check value; and the determining whether an operating state of the driver chip is abnormal by determining whether a relationship between the checked value and the auxiliary check value meets a preset condition comprises:
comparing the checked value with the auxiliary check value to obtain a comparison result; and
determining that the operating state of the driver chip is abnormal when the comparison result indicates that the checked value and the auxiliary check value are not equal; or
determining that the operating state of the driver chip is normal when the comparison result indicates that the checked value and the auxiliary check value are equal; and
after the determining that the operating state of the driver chip is abnormal when the comparison result indicates that the checked value and the auxiliary check value are not equal, the state self-test method further comprises: returning to the step of performing initialization of the first-type registers based on a received initialization instruction, and receiving and storing an auxiliary check value.

6. The state self-test method for a driver chip according to claim 2, wherein the auxiliary check value is equal to a difference between a preset value and a sum of the target register values of the first-type registers; and
the calculating a checked value based on a received state self-test instruction and actual register values of the first-type registers comprises: determining a sum of the actual register values of the first-type registers as the checked value based on the received state self-test instruction.

7. The state self-test method for a driver chip according to claim 6, wherein the preset condition is a sum of the checked value and the auxiliary check value being equal to the preset value; and the determining whether an operating state of the driver chip is abnormal by determining whether a relationship between the checked value and the auxiliary check value meets a preset condition comprises:
comparing the sum of the checked value and the auxiliary check value with the preset value to obtain a comparison result; and
determining that the operating state of the driver chip is abnormal when the comparison result indicates that the sum and the preset value are not equal; or
determining that the operating state of the driver chip is normal when the comparison result indicates that the sum and the preset value are equal; and
after the determining that the operating state of the driver chip is abnormal when the comparison result indicates that the sum and the preset value are not equal, the state self-test method further comprises: returning to the step of performing initialization of the first-type registers based on a received initialization instruction, and receiving and storing an auxiliary check value.

8. The state self-test method for a driver chip according to claim 2, wherein the driver chip further comprises second-type registers; and the performing initialization of the first-type registers based on a received initialization instruction, and receiving and storing an auxiliary check value comprises:
performing the initialization of the first-type registers based on the received initialization instruction, and receiving the auxiliary check value and storing the auxiliary check value in the second-type registers.

9. The state self-test method for a driver chip according to claim 8, wherein the auxiliary check value is equal to a difference between a preset value and a sum of the target register values of the first-type registers; the checked value is equal to a difference between the preset value and a sum of the actual register values of the first-type registers; and the preset value is equal to a maximum register value that the second-type registers are able to store;
the second-type registers comprise a first register, wherein the auxiliary check value is stored in the first register; and
the driver chip is configured to output a data voltage to a display screen body based on received display-related data, wherein the second-type registers are configured to store data other than the display-related data.

10. The state self-test method for a driver chip according to claim 8, wherein at least one of the second-type registers comprises a reset flag bit; and prior to the performing initialization of the first-type registers based on a received initialization instruction, and receiving and storing an auxiliary check value, the state self-test method further comprises:
receiving a reset instruction, and writing a reset flag bit value included in the reset instruction into the reset flag bit; and
resetting the second-type registers when the reset flag bit value of the reset flag bit is valid;
at least one of the second-type registers comprises a self-test enable flag bit; and the state self-test instruction comprises a self-test enable flag bit value; and
the calculating a checked value based on a received state self-test instruction and actual register values of the first-type registers comprises:
storing the self-test enable flag bit value in the self-test enable flag bit based on the received state self-test instruction; and
calculating the checked value based on the actual register values of the first-type registers when the self-test enable flag bit value is valid; and
the second-type registers further comprise a second register, wherein the second register comprises the reset flag bit and the self-test enable flag bit.

11. The state self-test method for a driver chip according to claim 8, wherein at least one of the second-type registers further comprises a self-test result flag bit; and
the determining whether an operating state of the driver chip is abnormal by determining whether a relationship between the checked value and the auxiliary check value meets a preset condition comprises:
determining the operating state of the driver chip by determining whether the relationship between the checked value and the auxiliary check value meets the preset condition, and storing a first numerical value in the self-test result flag bit when the operating state of the driver chip is abnormal; and
determining the operating state of the driver chip by determining whether the relationship between the checked value and the auxiliary check value meets the preset condition, and storing a second numerical value in the self-test result flag bit when the operating state of the driver chip is normal, wherein the second numerical value is different from the first numerical value.

12. The state self-test method for a driver chip according to claim 11, wherein the second-type registers comprise a second register, wherein the second register comprises the self-test result flag bit;
the second register further comprises a reset flag bit, a self-test enable flag bit, a pre-check result flag bit, and at least one first check data bit, wherein the first check data bit is used to store a first check data value; the first check data value of the first check data bit is related to a sum of numerical values of set flag bits, the set flag bits comprising the reset flag bit, the self-test enable flag bit, the pre-check result flag bit, and the self-test result flag bit; and a numerical value stored in the pre-check result flag bit is used to represent a pre-check result of pre-checking the first check data value and the numerical values of the set flag bits; and
the calculating a checked value based on a received state self-test instruction and actual register values of the first-type registers comprises:
writing corresponding data values into the reset flag bit, the self-test enable flag bit, the pre-check result flag bit, and the first check data bit based on the state self-test instruction;
determining a pre-check result based on a first sum value obtained by summing the data values corresponding to the reset flag bit, the self-test enable flag bit, the pre-check result flag bit, and the first check data bit, wherein when the first sum value is not equal to a first set value, it is determined that the pre-check result is incorrect; and when the first sum value is equal to the first set value, it is determined that the pre-check result is correct; and
writing a third numerical value into the pre-check result flag bit when the pre-check result is incorrect; or
writing a fourth numerical value into the pre-check result flag bit when the pre-check result is correct, and calculating the checked value based on the actual register values of the first-type registers when a self-test enable flag bit value of the self-test enable flag bit is valid, wherein the third numerical value is different from the fourth numerical value;
the data value corresponding to the pre-check result flag bit and included in the state self-test instruction is the fourth numerical value; and
the state self-test instruction comprises an invalid reset flag bit value corresponding to the reset flag bit.

13. The state self-test method for a driver chip according to claim 1, wherein the state self-test instruction further comprises self-test interval time data; and
the calculating a checked value based on a received state self-test instruction and actual register values of the first-type registers comprises:
obtaining a self-test interval time based on the self-test interval time data in the state self-test instruction, and calculating the checked value based on the actual register values of the first-type registers every self-test interval time;
and wherein the driver chip further comprises second-type registers, wherein the self-test interval time is stored in the second-type registers;
the second-type registers comprise a third register, wherein the third register comprises a self-test interval time data bit, and the self-test interval time data is stored in the self-test interval time data bit; and
the third register further comprises at least one second check data bit, wherein a second check data value of the second check data bit is related to a self-test interval time data value of the self-test interval time data bit.

14. The state self-test method for a driver chip according to claim 1, wherein the determining whether an operating state of the driver chip is abnormal by determining whether a relationship between the checked value and the auxiliary check value meets a preset condition comprises:
obtaining a self-test result by determining whether the relationship between the checked value and the auxiliary check value meets the preset condition, and determining, based on the self-test result and a signal output by at least one functional circuit module in the driver chip, whether the operating state of the driver chip is abnormal; and
determining that the operating state of the driver chip is normal, when the self-test result is normal and the signal output by the at least one functional circuit module in the driver chip is a first level signal; or determining that the operating state of the driver chip is abnormal, when the self-test result is abnormal or the signal output by the at least one functional circuit module in the driver chip is a second level signal;
the state self-test method further comprises:
reporting, when the operating state is abnormal, an abnormal operating state through a communication pin connected to the functional circuit module;
the functional circuit module comprises a clock lock detection circuit configured to output an out-of-lock signal when data received by the driver chip is out of lock; and
the driver chip further comprises second-type registers, at least one of the second-type registers comprising a self-test enable flag bit; and the state self-test method further comprises:
determining that the self-test result is normal when the self-test enable flag bit has an invalid value.

15. The state self-test method for a driver chip according to claim 1, wherein after the determining whether an operating state of the driver chip is abnormal by determining whether a relationship between the checked value and the auxiliary check value meets a preset condition, the state self-test method further comprises:
reporting, upon determining that the operating state of the driver chip is abnormal, an abnormal operating state based on a received self-test state query request or reporting the abnormal operating state actively.

16. A state self-test method for a driver chip, applied to a timing controller, the state self-test method comprising:
sending an initialization instruction to the driver chip, the initialization instruction comprising target register values of first-type registers in the driver chip, determining an auxiliary check value based on the target register values, and sending the auxiliary check value to the driver chip;
sending a state self-test instruction to the driver chip; and
receiving an operating state reported by the driver chip.

17. The state self-test method according to claim 16, wherein prior to the receiving an operating state reported by the driver chip, the state self-test method further comprises: sending a self-test state query request to the driver chip;
the sending a state self-test instruction to the driver chip comprises: sending the state self-test instruction to the driver chip, so that the driver chip calculates a checked value based on actual register values of the first-type registers after receiving the state self-test instruction, and determines whether the operating state of the driver chip is abnormal by determining whether a relationship between the checked value and the auxiliary check value meets a preset condition; and
the driver chip further comprises second-type registers, the second-type registers comprising a second register; and prior to the sending a self-test state query request to the driver chip, the state self-test method further comprises: reading numerical values of set flag bits and a first check data value of a first check data bit in the second register in the driver chip, and calculating a sum of the numerical values of the set flag bits and the first check data value to obtain a first sum value, wherein the set flag bits comprise a reset flag bit, a self-test enable flag bit, a pre-check result flag bit, and a self-test result flag bit; and the state self-test method further comprises: sending the self-test state query request to the driver chip when the first sum value is equal to a first set value; or returning to the step of reading numerical values of set flag bits and a first check data value of a first check data bit in the second register in the driver chip, and calculating a sum of the numerical values of the set flag bits and the first check data value to obtain a first sum value, when the first sum value is not equal to the first set value; or
the driver chip further comprises second-type registers, the second-type registers comprising a third register; and prior to the sending a self-test state query request to the driver chip, the state self-test method further comprises: reading a self-test interval time data value of a self-test interval time data bit and a second check data value of a second check data bit in the third register in the driver chip, and calculating a sum of the self-test interval time data value and the second check data value to obtain a second sum value; and
the state self-test method further comprises: sending the self-test state query request to the driver chip when the second sum value is equal to a second set value; or returning to the step of reading a self-test interval time data value of a self-test interval time data bit and a second check data value of a second check data bit in the third register in the driver chip, and calculating a sum of the self-test interval time data value and the second check data value to obtain a second sum value, when the second sum value is not equal to the second set value.

18. A driver chip, comprising first-type registers, a storage module, a calculation module, and a determination module, wherein
the calculation module is electrically connected to the first-type registers and the determination module, and is configured to calculate a checked value based on actual register values of the first-type registers; the storage module is configured to store an auxiliary check value; and the determination module is electrically connected to the storage module, and is configured to determine whether an operating state of the driver chip is abnormal by determining whether a relationship between the auxiliary check value and the checked value meets a preset condition.

19. The driver chip according to claim 18, wherein the auxiliary check value is related to target register values of the first-type registers after initialization;
the calculation module comprises a first adder configured to add the actual register values of the first-type registers to obtain a sum of the actual register values of the first-type registers;
the sum of the actual register values of the first-type registers is used as the checked value; the auxiliary check value is equal to a sum of the target register values of the first-type registers; and the determination module comprises a comparator configured to compare the checked value with the auxiliary check value and output a comparison result to determine whether the operating state of the driver chip is abnormal;
the sum of the actual register values of the first-type registers is used as the checked value; the auxiliary check value is equal to a difference between a preset value and the sum of the target register values of the first-type registers; the calculation module further comprises a second adder configured to sum the checked value and the auxiliary check value to obtain a checked sum value; and the determination module comprises a comparator configured to compare the checked sum value with the preset value and output a comparison result to determine whether the operating state of the driver chip is abnormal; and
the storage module comprises second-type registers, wherein the auxiliary check value is stored in the second-type registers.

20. The driver chip according to claim 19, wherein the driver chip further comprises a functional circuit module; the determination module further comprises an AND gate, wherein an output terminal of the comparator is electrically connected to a first input terminal of the AND gate, an output terminal of the functional circuit module is electrically connected to a second input terminal of the AND gate, and an output terminal of the AND gate is electrically connected to a communication pin of the driver chip; and the functional circuit module comprises a clock lock detection circuit configured to output an out-of-lock signal when data received by the driver chip is out of lock.
